(19) United States
(12) Patent Application Publication
(10) Pub. No.: US 2021/0135137 A1
(43) Pub. Date: May 6, 2021

(54) LIGHT EMITTING DEVICE AND MANUFACTURING APPARATUS OF LIGHT EMITTING DEVICE

(71) Applicant: SHARP KABUSHIKI KAISHA, Sakai city, Osaka (JP)

(72) Inventors: YUTO TSUKAMOTO, Sakai City, Osaka (JP); SHINICHI KAWATO, Sakai City, Osaka (JP); TOKIYOSHI UMEDA, Sakai City, Osaka (JP); MANABU NIBOSHI, Sakai City, Osaka (JP); YOUHEI NAKANISHI, Sakai City, Osaka (JP); HISAYUKI UTSUMI, Sakai City, Osaka (JP); MASAYUKI KANEHIRO, Sakai City, Osaka (JP); SHOTA OKAMOTO, Sakai City, Osaka (JP)

(21) Appl. No.: 16/644,042

(22) PCT Filed: Sep. 5, 2017
(86) PCT No.: PCT/JP2017/031895

§ 371 Date: Mar. 3, 2020

(51) Int. Cl. H01L 51/50; H01L 51/56

(52) U.S. Cl. CPC H01L 51/502; H01L 51/56

(57) ABSTRACT

To provide a light-emitting device that easily generates energy transition to fluorescent materials having a peak of the light emission spectrum in the deep-blue region and has improved efficiency of light emission, provided is a light-emitting device including a light-emitting layer in which quantum dots and light emitters being phosphors or phosphorescent members are dispersed, a first electrode in a lower layer than the light-emitting layer, and a second electrode in an upper layer than the light-emitting layer, wherein a light emission spectrum of the quantum dots and an absorption spectrum of the light emitters at least partially overlap each other.

### TECHNICAL FIELD

The present invention relates to a light-emitting device including a light-emitting element including quantum dots and a manufacturing apparatus of the light-emitting device.

### BACKGROUND ART

PTL 1 describes a light-emitting element provided with a light-emitting layer in which a material that emits thermally activated delayed fluorescence (TADF) and a material that emits fluorescence is mixed to improve luminous efficiency.

In the light-emitting element of PTL 1, a singlet excitation state of the TADF material is created from a triplet excitation state of the TADF material by reverse intersystem crossing. Then, the singlet excitation state of the TADF material transitions to the singlet excitation state of the fluorescent material by the Förster transition to generate fluorescence.

### CITATION LIST

### Patent Literature

PTL 1: JP 2014-45179A (published on Mar. 13, 2014)

### SUMMARY OF INVENTION

### Technical Problem

An energy gap between a triplet excitation level and a singlet excitation level of the TADF material is very small. Thus, in the light-emitting element of PTL 1, the triplet excitation state of the TADF material is easily created from the singlet excitation state of the TADF material by intersystem crossing. In this state, a Dexter transition from the triplet excitation state of the TADF material to the triplet excitation state of the fluorescent material may occur. The deactivation process of the fluorescent material from the triplet excitation state to the ground state is a non-light emission process. Therefore, in the light-emitting element of PTL 1, the luminous efficiency may be reduced.

It is also difficult to synthesize a quantum efficient TADF material having a peak wavelength of the light emission spectrum in a short wavelength region such as the violet region. Thus, it is difficult to transition energy from the TADF material to a fluorescent material having a peak of the light emission spectrum in the deep-blue region.

### Solution to Problem

To solve the above-mentioned problems, a light-emitting device according to the present invention includes: a light-emitting layer in which quantum dots and light emitters being phosphors or phosphorescent members are dispersed; a first electrode in a lower layer than the light-emitting layer; and a second electrode in an upper layer than the light-emitting layer, wherein a light emission spectrum of the quantum dots and an absorption spectrum of the light emitters at least partially overlap each other.

### Advantageous Effects of Invention

According to the configuration described above, the efficiency of light emission of the light emitters can be improved. It is relatively easy to generate an energy transition in light emitters having a peak of the light emission spectrum in the deep-blue region.

### BRIEF DESCRIPTION OF DRAWINGS

FIG. 1 is a schematic cross-sectional view of a light-emitting device according to a first embodiment of the present invention, and a diagram illustrating examples of a light emission spectrum of quantum dots and an absorption spectrum of phosphors of the light-emitting device.

FIG. 2 illustrates a molecular orbit diagram of a quantum dot and a phosphor in the light-emitting device according to the first embodiment of the present invention, and a light emission mechanism of the light-emitting device.

FIG. 3 is a schematic top view and a schematic cross-sectional view of a light-emitting device according to a second embodiment of the present invention.

FIG. 4 is a schematic top view illustrating a relationship of positions at which an edge cover and a light-emitting layer are formed in the light-emitting device according to the second embodiment of the present invention.

FIG. 5 illustrates examples of a light emission spectrum of quantum dots and an absorption spectrum of phosphors in a red pixel area of the light-emitting device according to the second embodiment of the present invention.

FIG. 6 illustrates examples of a light emission spectrum of quantum dots and an absorption spectrum of phosphors in a green pixel area of the light-emitting device according to the second embodiment of the present invention.

FIG. 7 illustrates examples of a light emission spectrum of quantum dots and an absorption spectrum of phosphors in a blue pixel area of the light-emitting device according to the second embodiment of the present invention.

FIG. 8 is a block diagram illustrating a manufacturing apparatus of the light-emitting device according to the embodiments of the present invention.

### DESCRIPTION OF EMBODIMENTS

In the present specification, the direction from the light-emitting layer to the first electrode of the light-emitting device is referred to as “lower direction”, and the direction from the light-emitting layer to the second electrode of the light-emitting device is referred to as “upper direction”.

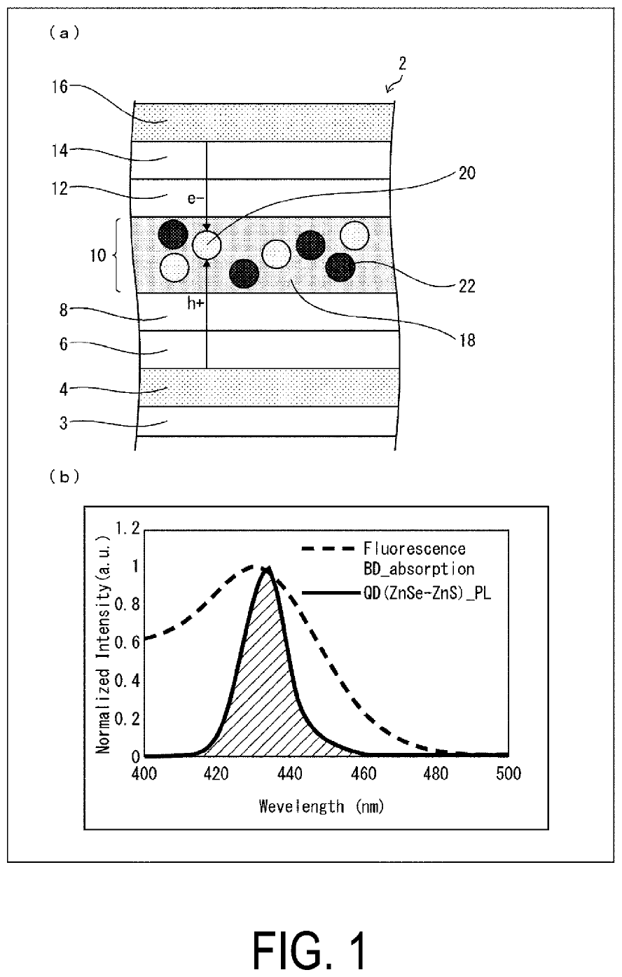

(a) of FIG. 1 is a schematic cross-sectional view of a light-emitting device 2 according to the present embodiment.

As illustrated in (a) of FIG. 1, the light-emitting device 2 has a structure in which layers are stacked on an array substrate 3 including a Thin Film Transistor (TFT) not illustrated. A first electrode 4 formed in the upper layer of the array substrate 3 is electrically connected with the TFT of the array substrate 3. The light-emitting device 2 includes, on the first electrode 4, a hole injection layer 6, a hole transport layer 8, a light-emitting layer 10, an electron transport layer 12, an electron injection layer 14, and a second electrode 16 in this order from the lower layer. In the present embodiment, the first electrode 4 is an anode and the second electrode 16 is a cathode.

The light-emitting layer 10 includes a host 18, quantum dots (semiconductor nanoparticles) 20, and phosphors 22 as light emitters. The quantum dots 20 and phosphor 22 are dispersed in the host 18.

The host 18 includes a compound having a function of injecting and transporting holes and electrons. The host 18 may include a photosensitive material. The host 18 may further include a dispersing material not illustrated.

In the light-emitting device 2, when a potential difference is applied between the first electrode 4 and the second electrode 16, holes and electrons are injected into the light-emitting layer 10 from the first electrode 4 and the second electrode 16, respectively. As illustrated in (a) of FIG. 1, a hole from the first electrode 4 reaches the light-emitting layer 10 through the hole injection layer 6 and the hole transport layer 8. An electron from the second electrode 16 reaches the light-emitting layer 10 through the electron injection layer 14 and the electron transport layer 12.

The hole and electron having reached the light-emitting layer 10 are recombined in the quantum dots 20 through the host 18, and an exciton is generated. The hole transport properties of the hole injection layer 6 and the hole transport layer 8 and the electron transport properties of the electron injection layer 14 and the electron transport layer 12 are adjusted such that excitons are generated in the light-emitting layer 10 as described above.

The quantum dots 20 have a valence band level and a conduction band level. When energy is applied to the quantum dot 20 from an exciton generated by a recombination of a hole and an electron, the exciton is excited from the valence band level to the conduction band level of the quantum dot 20. The quantum dot 20 may be a semiconductor nanoparticle having a core-shell structure with a CdSe core and a ZnS shell, for example.

The phosphor 22 is a fluorescent material that has a ground level, a singlet excitation level and a triplet excitation level, and emits fluorescence when an exciton excited from the ground level to the singlet excitation level transitions to the ground level.

(b) of FIG. 1 is a spectrum graph in which an example of the fluorescence spectrum of the quantum dots 20 is indicated by a solid line and an example of the absorption spectrum of the phosphors 22 is indicated by a broken line. The hatched area in (b) of FIG. 1 indicates an area where the fluorescence spectrum of the quantum dots 20 and the absorption spectrum of the phosphors 22 overlap. In the spectrum graphs of the present specification, the horizontal axis indicates the wavelength and the vertical axis indicates the normalized spectrum intensity. The spectrums in (b) of FIG. 1 are normalized with respect to the maximum intensity set to 1.

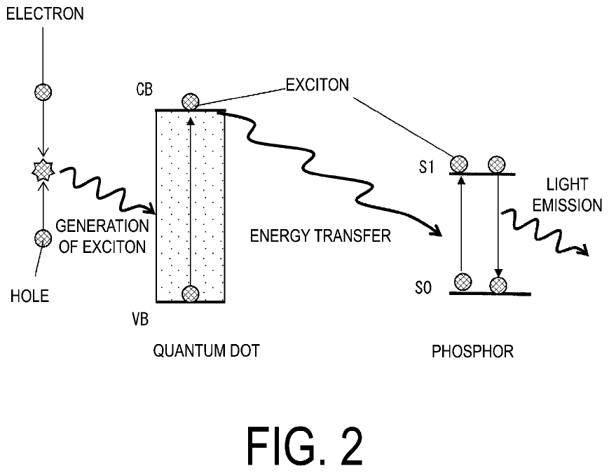

FIG. 2 is a diagram illustrating a light emission mechanism of the light-emitting device 2 according to the present embodiment. Left and right molecular orbit diagrams of FIG. 2 illustrate molecular orbits of the quantum dots 20 and the phosphors 22, respectively. Note that, in the molecular orbit diagram of the quantum dot, VB represents the valence band level and CB represents the conduction band level. In the molecular orbit diagram of the phosphor, S0 represents the ground level and S1 represents the singlet excitation level, and, the triplet excitation level is omitted in the diagram. Note that, in the present embodiment, the conduction band level of the quantum dots 20 is higher than the singlet excitation level of the phosphors 22 as illustrated in FIG. 2. This means that the peak wavelength of the light emission spectrum of the quantum dots 20 is shorter than the peak wavelength of the light emission spectrum of the phosphors 22.

The light emission mechanism of light-emitting device 2 according to the present embodiment is described in detail with reference to FIG. 1 and FIG. 2.

As illustrated in FIG. 2, in a case where a hole and an electron at least having reached the light-emitting layer 10 recombine in the quantum dot 20 through the host 18, an exciton is generated at the quantum dot 20 resulting from the recombination of the hole and the electron. The exciton is excited from the valence band level to the conduction band level of the quantum dots 20.

Here, energy transfer of the Forster mechanism causes the exciton of the conduction band level of the quantum dots 20 to transition to the singlet excitation level of the phosphors 22. In the present embodiment, the Forster mechanism is a mechanism of energy transfer that is caused by a resonance phenomenon of dipole vibrations between the quantum dots 20 and the phosphors 22. The energy transfer of the Förster mechanism does not require direct contact between the quantum dots 20 and the phosphors 22. When the velocity constant of the Forster mechanism is represented by k_{h*→g}, k_{h*→g} is expressed by Equation (1).

$${k}_{{h}^{*} \to g} = \frac{9000 {c}^{4} {K}^{2} ϕln10}{128 {π}^{5} {n}^{4} N τ {R}^{6}} \int \frac{{f}_{h}^{′} ( v ) {ɛ}_{g} ( v )}{{v}^{4}} dv , \qquad [ Equation 1 ]$$

where v represents the number of vibrations, f′ₕ(v) represents a normalized fluorescence spectrum of the quantum dots 20, ε_{g}(v) represents a molar absorption coefficient of the phosphors 22, N represents an Avogadro's number, n represents the refractive index of the host 18, R represents an intermolecular distance between the quantum dots 20 and the phosphors 22, τ represents a fluorescence lifetime of the excitation state of the quantum dots 20, the fluorescence lifetime being actually measured, φ represents a fluorescence quantum yield of the quantum dots 20, and K is a coefficient representing an orientation of the transition dipole moment of the quantum dots 20 and the phosphors 22. Note that, in a case of random orientation, K²=2/3.

The greater the velocity constant k_{h*→g}, the more the energy transfer of the Forster mechanism becomes dominant. In view of this, the energy transfer from the quantum dots 20 to the phosphors 22 requires overlapping between the light emission spectrum of the quantum dots 20 and the absorption spectrum of the phosphors 22.

As illustrated in (b) of FIG. 1, in the present embodiment, the fluorescence spectrum of the quantum dots 20 and the absorption spectrum of the phosphors 22 at least partially overlap. With this configuration, the above-described energy transfer occurs between the quantum dot 20 and the phosphor 22 whose intermolecular distance is sufficiently small.

In addition, as illustrated in (b) of FIG. 1, in the present embodiment, the peak wavelength of the light emission spectrum of the quantum dots 20 is included in the absorption spectrum of the phosphors 22. In addition, the peak wavelength of the absorption spectrum of the phosphors 22 is included in the light emission spectrum of the quantum dots 20. With this configuration, the energy transfer described above more dominantly occurs.

Finally, when an exciton transitions from the singlet excitation level to the ground level of the phosphor 22, fluorescence having energy equal to the energy difference between the singlet excitation level and the ground level is emitted from the phosphor 22. With the mechanism described above, fluorescence is obtained from the light-emitting device 2.

In the light-emitting device 2 according to the present embodiment, the generated exciton moves from the quantum dot 20 to the phosphor 22 due to the energy transfer of the Förster mechanism, resulting in fluorescence in the phosphor 22. In the energy transfer from the quantum dot 20 to the phosphor 22, a Dexter transition that generates a non-light emission process does not occur. Therefore, the light-emitting device 2 according to the present embodiment is capable of obtaining fluorescence more efficiently from the exciton that causes energy transfer to the phosphor 22.

Quantum dots that emit fluorescence at short wavelengths in the violet region or ultraviolet region are easier to synthesize compared to thermally activated delayed fluorescence bodies. That is, quantum dots that efficiently transition energy to fluorescent materials having a peak of the light emission spectrum in the deep-blue region are easier to synthesize compared to thermally activated delayed fluorescence bodies. Therefore, the light-emitting device 2 according to the present embodiment can be more easily manufactured than conventionally, and is capable of efficiently obtaining fluorescence in the deep-blue region. Here, the light of the violet region or the ultraviolet region is a light having the central wavelength of the light emission in a wavelength band equal to or shorter than 420 nm.

The concentration of the quantum dots 20 in the light-emitting layer 10 is 0.1 to 1 mass %, for example. When the concentration of the quantum dots 20 falls within the range described above, a decrease in luminous efficiency due to concentration reduction can be reduced, and generation of excitons in the dispersing material can be suppressed.

In addition, the concentration of the phosphors 22 in the light-emitting layer is 10 to 30 mass %. When the concentration of the phosphors 22 falls within the range described above, the energy transfer described above can be efficiently caused to occur.

Note that in the present embodiment, the light-emitting layer 10 includes phosphors 22 as light emitters. However, the light-emitting layer 10 is not limited to this, and the light-emitting layer 10 may include phosphorescent members that emit phosphorescence as light emitters instead of phosphors. In this case as well, energy transfer from the quantum dots to the phosphorescent members occurs due to the Forster mechanism. Thereafter, by intersystem crossing, the excitons transition from the singlet excitation level to the triplet excitation level of the phosphorescent members. In a case where excitons transition from the triplet excitation level to the ground level of the phosphorescent members, phosphorescence can be obtained from the phosphorescent members. Therefore, even in the above configuration, it is possible to obtain phosphorescence in the deep-blue region more efficiently.

### Second Embodiment

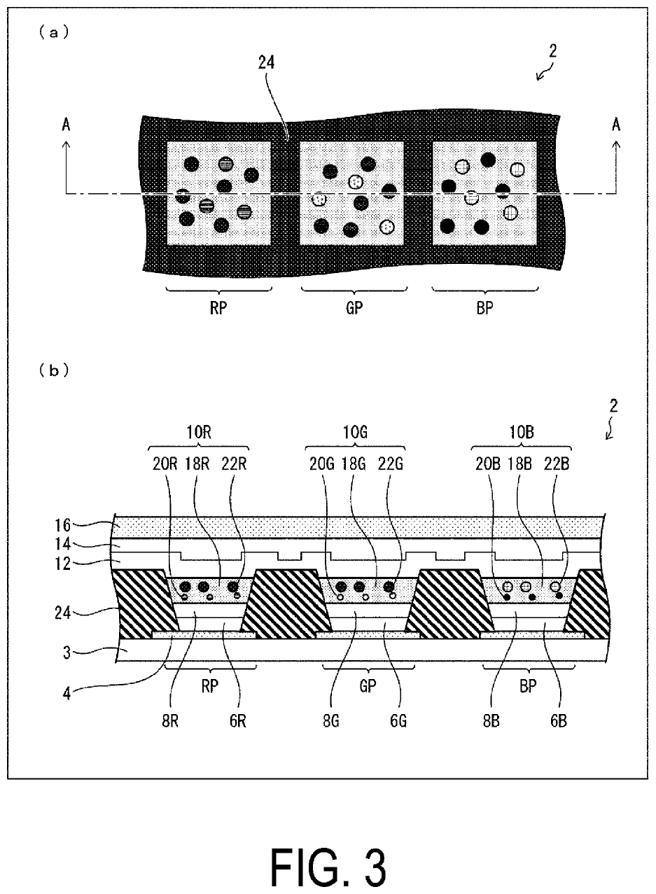

FIG. 3 is an enlarged top view and an enlarged cross-sectional view of the light-emitting device 2 according to the present embodiment. (a) of FIG. 3 is a diagram illustrating, through the electron transport layer 12, the electron injection layer 14 and the second electrode 16, the upper face of a region around pixels of the light-emitting device 2. (b) of FIG. 3 is a cross-sectional view taken along the line A-A of (a) of FIG. 3.

In the present embodiment, the light-emitting device 2 includes a plurality of pixel areas, RP, GP and BP in comparison with the preceding embodiment. In the pixel area RP, a hole injection layer 6R, a hole transport layer 8R, and a light-emitting layer OR are formed on the first electrode 4 in this order from the lower side. Likewise, in the pixel areas GP and BP, hole injection layers 6G and 6B, hole transport layers 8G and 8B, and light-emitting layers 10G and 10B are respectively formed in this order from the lower side. The light-emitting device 2 further includes an edge cover 24. The edge cover 24 includes a plurality of openings and defines the plurality of pixel areas RP, GP and BP.

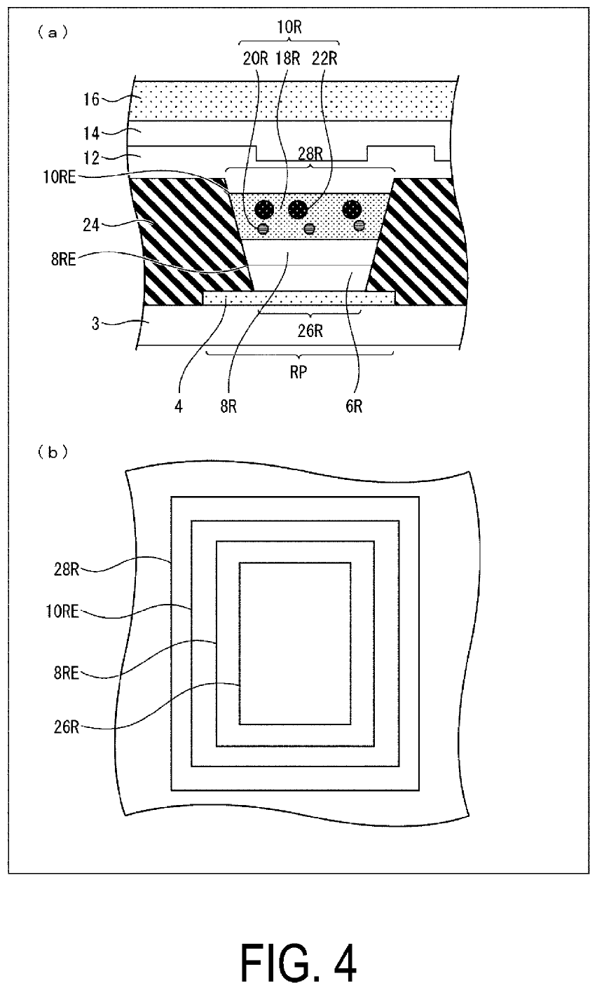

FIG. 4 is a diagram illustrating a relationship of formation positions of the edge cover and the light-emitting layer of the light-emitting device 2 according to the present embodiment. (a) of FIG. 4 is an enlarged side cross-sectional view of the pixel area RP in FIG. 3. (b) of FIG. 4 is a top view illustrating formation positions of an opening of the edge cover and the light-emitting layer in the pixel area RP.

As illustrated in (a) of FIG. 4, the edge cover 24 includes an opening 26R and an upper end 28R in the pixel area RP. The opening 26R is smaller than the upper end 28R, and the pore of the edge cover 24 extends from the opening 26R up to the upper end 28R with the cross-sectional area of the pore being gradually increased.

Accordingly, as illustrated in (a) and (b) of FIG. 4, a lower end 8RE of the hole transport layer 8R is larger than the opening 26R of the edge cover 24. In other words, the light-emitting layer 10R in an upper layer than the hole transport layer 8R covers the opening 26R of the edge cover 24. The upper end 28R of the edge cover 24 is above the upper end 10RE of the light-emitting layer 10R. In other words, the upper end 28R of the edge cover 24 surrounds the light-emitting layer 10R.

Referring to FIG. 3 again, the light-emitting layer 10R in the pixel area RP includes a host 18R, quantum dots 20R, and phosphors 22R. Likewise, the light-emitting layer 10G in the pixel area GP includes an host 18G, quantum dots 20G, and phosphors 22G, and the light-emitting layer 10B in the pixel area BP includes an host 18B, quantum dots 20B, and phosphors 228.

In the present embodiment, the light-emitting layers 10R, 10G and 10B in one of the pixel areas RP, GP and BP has phosphors different from the phosphors of the light-emitting layers 10R, 10G and 10B of other different pixel areas. For example, in the present embodiment, the light-emitting layer 10R in the pixel area RP includes the phosphors 22R that emit red light as fluorescence. Likewise, the light-emitting layer 10G in the pixel area GP includes the phosphors 22G that emit green light as fluorescence, and the light-emitting layer 10B in the pixel area BP includes the phosphors 22B that emit blue light as fluorescence.

Here, the blue light is light having the central wavelength of the light emission in a wavelength band from 400 nm to 500 nm. The green light is light having the central wavelength of the light emission in a wavelength band longer than 500 nm and shorter than or equal to 600 nm. The red light is light having the central wavelength of the light emission in a wavelength band longer than 600 nm and shorter than or equal to 780 nm.

The light-emitting layers 10R, 10G and 10B in some of the plurality of pixel areas RP, GP and BP may include a host or quantum dots different from the host or the quantum dots of the light-emitting layers 10R, 10G and 10B in other different pixel areas. However, in the present embodiment, the hosts 18R, 18G and 18B and the quantum dots 20R, 20G and 20B in the pixel areas may include the same member.

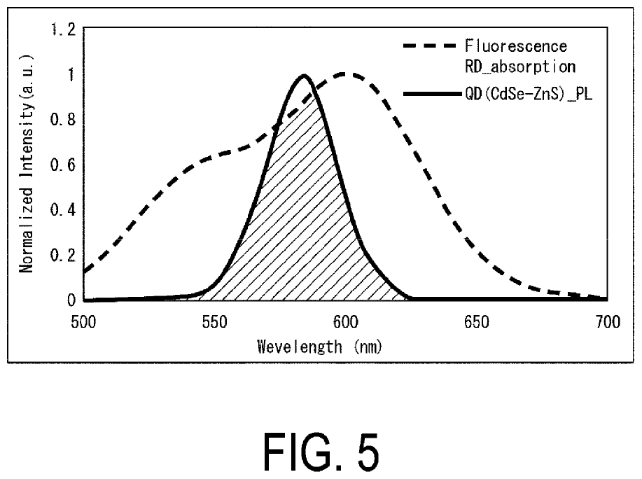

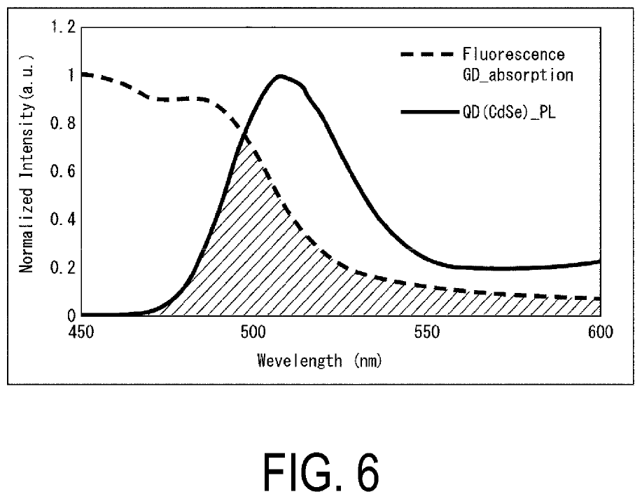

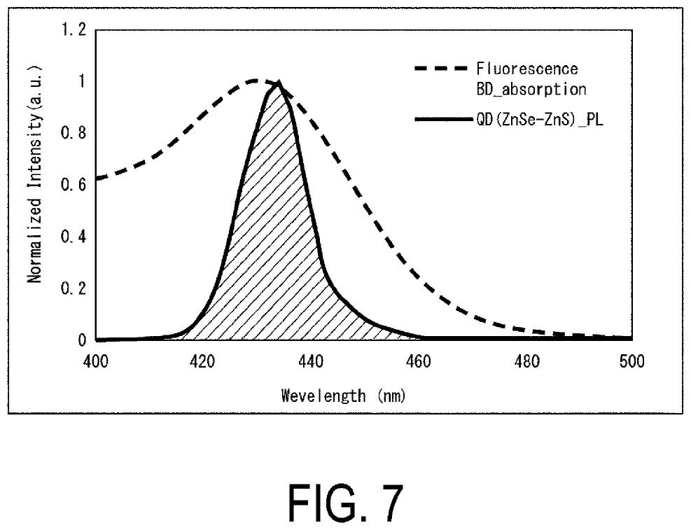

FIG. 5 is a spectrum graph in which an exemplary fluorescence spectrum of the quantum dots 20R is indicated with a solid line, and an exemplary absorption spectrum of the phosphors 22R is indicated with a broken line. FIG. 6 is a spectrum graph in which an exemplary fluorescence spectrum of the quantum dots 20G is indicated with a solid line, and an exemplary absorption spectrum of the phosphors 22G is indicated with a broken line. FIG. 7 is a spectrum graph in which an exemplary fluorescence spectrum of the quantum dots 20B is indicated with a solid line, and an exemplary absorption spectrum of the phosphors 22B is indicated with a broken line. In FIGS. 5 to 7, the hatched area indicates an area where the fluorescence spectrum of the quantum dots and the absorption spectrum of the phosphors overlap. The spectrums in FIGS. 5 to 7 are normalized with respect to the maximum intensity set to 1.

In the present embodiment, the quantum dots 20R are CdSe—ZnS quantum dots manufactured by Mesolight LLC. The quantum dots 20G are CdSe quantum dots manufactured by Sigma Aldrich. The quantum dots 20B are ZnSe—ZnS quantum dots manufactured by Sigma Aldrich.

As illustrated in FIGS. 5 to 7, regarding the quantum dots and the phosphors included in the same pixel area, the light emission spectrum of the quantum dots and the absorption spectrum of the phosphors at least partially overlap. With this configuration, the light-emitting device 2 according to the present embodiment emits fluorescence by using a light emission mechanism similar to that of the light-emitting device 2 according to the preceding embodiment. Therefore, in the present embodiment as well, similar to the preceding embodiment, a light-emitting device 2 that can efficiently obtain fluorescence from phosphors is obtained.

The wavelengths of the fluorescence from the phosphors in the pixel areas are different from each other, and therefore, by controlling the TFTs to control the light emission from the phosphors in the pixel areas, the light-emitting device 2 capable of performing multi-color display can be provided.

Note that in the present embodiment as well, the light-emitting layers 10R and 10G in the pixel areas RP and GP may include phosphorescent members that emit phosphorescence as light emitters instead of phosphors. In this case as well, energy transfer from the quantum dots to the phosphorescent members in the pixel areas RP and GP occurs due to the Forster mechanism. Phosphorescent members that emit red light and green light as phosphorescence are relatively easy to synthesize, and light emission can be efficiently obtained from excitons that are energy transferred from the quantum dots.

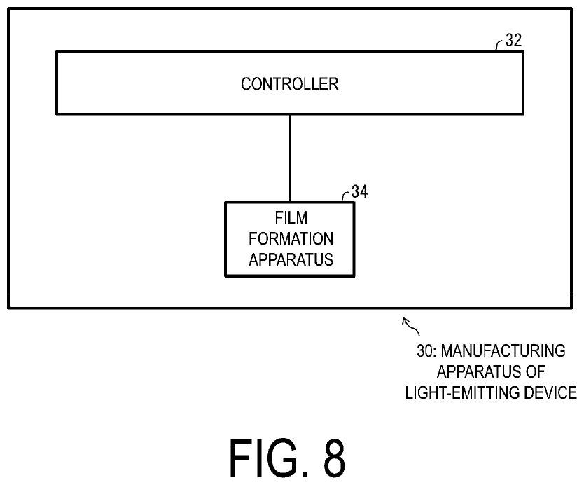

FIG. 8 is a block diagram illustrating a manufacturing apparatus 30 of the light-emitting device according to the embodiments. The manufacturing apparatus 30 of the light-emitting device may include a controller 32 and a film formation apparatus 34. The controller 32 may control the film formation apparatus 34. The film formation apparatus 34 may form each layer of the light-emitting device 2.

### Supplement

A light-emitting device according to a first aspect includes: a light-emitting layer in which quantum dots and light emitters being phosphors or phosphorescent members are dispersed; a first electrode in a lower layer than the light-emitting layer; and a second electrode in an upper layer than the light-emitting layer, wherein a light emission spectrum of the quantum dots and an absorption spectrum of the light emitters at least partially overlap each other.

In a second aspect, an exciton generated in the quantum dots transitions, through a resonance phenomenon of a dipole vibration, to an excitation level of the light emitters, and the light emitters emit light.

In third aspect, a peak wavelength of the light emission spectrum of the quantum dots is shorter than a peak wavelength of the light emission spectrum of the light emitters.

In a fourth aspect, the peak wavelength of the light emission spectrum of the quantum dots is included in the absorption spectrum of the light emitters.

In a fifth aspect, the peak wavelength of the absorption spectrum of the light emitters is included in the light emission spectrum of the quantum dots.

In a sixth aspect, a concentration of the quantum dots in the light-emitting layer is from 10 mass % to 30 mass %.

In a seventh aspect, a concentration of the light emitters in the light-emitting layer ranges from 0.1 to 1 mass %.

In an eighth aspect, an edge cover is provided, the edge cover including a plurality of openings, the edge cover being configured to define the light-emitting layer into a plurality of pixel areas, and for the plurality of openings, the light-emitting layer covers each of the plurality of openings, and an upper end of the edge cover surrounds the light-emitting layer.

In a ninth aspect, a peak wavelength of the light emission spectrum of the quantum dots is at least partially included in a violet region or an ultraviolet region.

In a tenth aspect, the light-emitting layer includes a photosensitive material, and the quantum dots and the light emitters are dispersed in the photosensitive material.

A manufacturing apparatus of a light-emitting device according to an eleventh aspect includes a film formation apparatus configured to form: a light-emitting layer in which quantum dots and light emitters being phosphors or phosphorescent members are dispersed, an absorption spectrum of the light emitters at least partially overlapping with a light emission spectrum of the quantum dots; a first electrode in a lower layer than the light-emitting layer; and a second electrode in an upper layer than the light-emitting layer.

The present invention is not limited to each of the embodiments described above, and various modifications may be made within the scope of the claims. Embodiments obtained by appropriately combining technical approaches disclosed in each of the different embodiments also fall within the technical scope of the present invention. Moreover, novel technical features can be formed by combining the technical approaches disclosed in the embodiments.

### REFERENCE SIGNS LIST

2 Light-emitting device
4 First electrode
10 Light-emitting layer
16 Second electrode
18 Host
20 Quantum dot
22 Phosphor

1. A light-emitting device comprising:
a light-emitting layer in which quantum dots and light emitters being phosphors or phosphorescent members are dispersed;
a first electrode in a lower layer than the light-emitting layer; and
a second electrode in an upper layer than the light-emitting layer,
wherein a light emission spectrum of the quantum dots and an absorption spectrum of the light emitters at least partially overlap each other.

2. The light-emitting device according to claim 1,
wherein an exciton generated at the quantum dots transitions, through a resonance phenomenon of a dipole vibration, to an excitation level of the light emitters, and the light emitters emit light.

3. The light-emitting device according to claim 1,
wherein a peak wavelength of the light emission spectrum of the quantum dots is shorter than a peak wavelength of a light emission spectrum of the light emitters.

4. The light-emitting device according to claim 1,
wherein a peak wavelength of the light emission spectrum of the quantum dots is included in the absorption spectrum of the light emitters.

5. The light-emitting device according to claim 1,
wherein a peak wavelength of the absorption spectrum of the light emitters is included in the light emission spectrum of the quantum dots.

6. The light-emitting device according to claim 1,
wherein a concentration of the quantum dots in the light-emitting layer is from 10 mass % to 30 mass %.

7. The light-emitting device according to claim 1,
wherein a concentration of the light emitters in the light-emitting layer is from 0.1 mass % to 1 mass %.

8. The light-emitting device according to claim 1,
wherein an edge cover is provided, the edge cover including a plurality of openings, the edge cover being configured to define the light-emitting layer into a plurality of pixel areas, and for each of the plurality of openings, the light-emitting layer covers the plurality of openings, and an upper end of the edge cover surrounds the light-emitting layer.

9. The light-emitting device according to claim 1,
wherein a peak wavelength of the light emission spectrum of the quantum dots is at least partially included in a violet region or an ultraviolet region.

10. The light-emitting device according to claim 1,
wherein the light-emitting layer includes a photosensitive material, and the quantum dots and the light emitters are dispersed in the photosensitive material.

11. A manufacturing apparatus of a light-emitting device, the manufacturing apparatus comprising:
a film formation apparatus configured to form
a light-emitting layer in which quantum dots and light emitters being phosphors or phosphorescent members are dispersed, an absorption spectrum of the light emitters at least partially overlapping with a light emission spectrum of the quantum dots,
a first electrode in a lower layer than the light-emitting layer, and
a second electrode in an upper layer than the light-emitting layer.
